(19) United States
(12) Patent Application Publication
(10) Pub. No.: US 2009/0141357 A1
(43) Pub. Date: Jun. 4, 2009

(54) PLASTIC LENS COMPRISING MULTILAYER ANTIREFLECTIVE FILM AND METHOD FOR MANUFACTURING SAME

(75) Inventors: Hitoshi KAMURA, Tokyo (JP); Yukihiro Takahashi, Tokyo (JP); Hisao Kawai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION, Tokyo (JP)

(21) Appl. No.: 12/277,929

(22) Filed: Nov. 25, 2008

(30) Foreign Application Priority Data
Nov. 27, 2007 (JP) 2007-306290

(51) Int. Cl. G02B 1/11; B05D 5/06; C23C 14/08; C23C 14/34

(52) U.S. Cl. 359/585; 427/162; 427/529; 204/192.1; 359/601

(57) ABSTRACT

The present invention relates to a plastic lens comprising a multilayer antireflective film and to a method for manufacturing the same. The plastic lens has a multilayer antireflective film present on the surface of a plastic lens substrate, either directly or through another layer. The multilayer antireflective film comprises a composite layer in which at least two metal oxide layers, containing an identical metal element but different quantities of oxygen, are adjacent. In the method for manufacturing the above plastic lens, each of the metal oxide layers constituting said composite layer is formed by employing a single vaporization source and by vapor depositing adjacent layers under differing conditions of partial pressure of reactive oxygen gas.

### CROSS-REFERENCE TO RELATED APPLICATIONS

This application claims benefit of priority under 35 USC 119 to Japanese Patent Application No. 2007-306290 filed on Nov. 27, 2007, which is expressly incorporated herein by reference in its entirety.

### BACKGROUND OF THE INVENTION

1. Field of the Invention

The present invention relates to a plastic lens comprising a multilayer antireflective film and to a method for manufacturing the same.

2. Discussion of the Background

The application of antireflective films to synthetic resin surfaces is a widely known method of improving the reflective characteristics of the surfaces of optical components comprised of synthetic resin, such as plastic lenses.

Since inorganic antireflective films have different coefficients of thermal expansion than plastic lens substrates, they generally exhibit poorer thermal characteristics than organic antireflective films (for example, Japanese Unexamined Patent Publication (KOKAI) No. 2005-234311, which is expressly incorporated herein by reference in their entirety. Japanese Unexamined Patent Publication (KOKAI) No. 2007-78780, which is expressly incorporated herein by reference in their entirety, discloses a method of manufacturing an antireflective film comprising both an inorganic layer, formed by vapor deposition, and an inorganic layer, applied as a coating, to compensate for the drawbacks of inorganic antireflective films. In Japanese Unexamined Patent Publication (KOKAI) No. 2007-78780, a highly antireflective inorganic layer is employed together with a highly heat resistant organic layer to achieve a plastic lens with good thermal resistance.

Electrically conductive antireflective films imparting an antistatic function (for example, U.S. Pat. No. 6,852,406, which is expressly incorporated herein by reference in their entirety) can be provided in addition to the above-described antireflective function on plastic lenses.

However, in the method described in Japanese Unexamined Patent Publication (KOKAI) No. 2007-78780, a low refractive index layer of organic material is formed on the surface of an antireflective film. Forming the antireflective film requires a vapor deposition method to form an inorganic layer and a coating step to form an organic layer, resulting in a complex manufacturing process. It is also necessary to keep the bonding surface extremely clean to improve adhesion between the organic layer and the inorganic layer. When separation due to poor adhesion and (organic layer) coating spots are present on the antireflective film imparting optical properties, the appearance of the lens that is obtained deteriorates or the antireflective effect diminishes. It is currently impractical to impart thermal characteristics by forming an antireflective film comprising both an organic layer and an inorganic layer that are formed by different means.

In the electrically conductive antireflective film described in U.S. Pat. No. 6,852,406, there is variation in the surface resistivity and the yield is poor. It is possible to obtain lenses with design values of electrical conductivity using conventional manufacturing methods, but there is a problem in the form of variation in quality.

Accordingly, one object of the present invention is to provide a plastic lens having an antireflective film with enhanced thermal resistance without employing an organic layer, and to provide a method for manufacturing the same.

The present invention further provides a plastic lens having an antireflective film with enhanced thermal resistance, achieved without employing an organic layer, in the form of a plastic lens having an electrically conductive antireflective film with little variation in surface resistivity, and a method for manufacturing the same.

### SUMMARY OF THE INVENTION

A feature of the present invention relates to a plastic lens having a multilayer antireflective film present on the surface of a plastic lens substrate, either directly or through another layer, wherein said multilayer antireflective film comprises a composite layer in which at least two metal oxide layers, containing an identical metal element but different quantities of oxygen, are adjacent.

A feature of the present invention relates to a method for manufacturing the above plastic lens of the present invention, wherein each of the metal oxide layers constituting said composite layer are formed by employing a single vaporization source to vapor deposit adjacent layers under differing conditions of partial pressure of reactive oxygen gas.

### BRIEF DESCRIPTION OF THE DRAWINGS

The present invention will be described in the following text by the exemplary, non-limiting embodiments shown in the figures, wherein:

FIG. 1 is a schematic drawing of the film configuration of Embodiment 1.

FIG. 2 is a schematic drawing of the film configuration of Comparative Example 1.

FIG. 3 is a graph of the surface resistivity of the embodiments and the comparative examples.

### DESCRIPTIONS OF THE EMBODIMENTS

The following preferred specific embodiments are, therefore, to be construed as merely illustrative, and not limitative of the remainder of the disclosure in any way whatsoever. In this regard, no attempt is made to show structural details of the present invention in more detail than is necessary for the fundamental understanding of the present invention, the description taken with the drawings making apparent to those skilled in the art how the several forms of the present invention may be embodied in practice.

The present invention provides a plastic lens having an antireflective film with improved thermal resistance without employing an organic layer, and a method for manufacturing the same.

The present invention further provides a plastic lens that has both an antireflective film with improved thermal resistance, achieved without employing an organic layer, and an electrically conductive antireflective film with little variation in surface resistivity, and a method for manufacturing the same.

### The Plastic Lens

The plastic lens of the present invention comprises a multilayer antireflective film formed on the surface of a plastic lens substrate, either directly or through another layer. The plastic lens of the present invention is characterized in that the multilayer antireflective film comprises a composite layer having at least two adjacent metal oxide layers the metal element of which is identical but the oxygen content of which differs.

In the present invention, the composite layer comprising at least two adjacent metal oxide layers is a layer in which an identical metal element is contained in the metal oxide layers but in which the oxygen content of these layers differs. For example, this composite layer can be comprised of two, three, four, or more metal oxide layers. Providing such a composite layer in which oxide layers comprising the same metal element but having different oxygen contents are superposed adjacent to each other in an antireflective film improves the thermal resistance property of such a plastic lens having an antireflective film.

Ensuring that at least one of the metal oxide layers constituting the composite layer has an oxygen content that is less than the stoichiometric quantity is desirable from the perspective of improving the thermal resistance effect. Having an oxygen content that is less than the stoichiometric quantity specifically means that oxygen is lacking within a proportion range of 0.1 to 20 molar percent relative to the stoichiometric quantity within the oxide. Creating such a state is appropriate for achieving a thermal resistance-enhancing effect.

All of the metal oxide layers constituting the composite layer can be comprised of oxides in which the oxygen content is less than the stoichiometric quantity. In that case, all of the metal oxide layers are comprised of oxides in which the oxygen content is less than the stoichiometric quantity and the oxygen content differs within a range that is less than the stoichiometric quantity.

Of the metal oxide layers constituting the composite layer, the thickness of the metal oxide layer with the lowest oxygen content is desirably 5 nm or lower. The lower the oxygen content of the oxide layer, the greater the absorption of visible light. Thus, when the thickness of the metal oxide layer with the lowest oxygen content is increased, coloration tends to become pronounced. When this fact and the effects obtained by providing a composite layer are considered, the thickness of the oxide layer is desirably 5 nm or lower. The lower limit of the thickness of the metal oxide layer with the lowest oxygen content is desirably 0.5 nm or higher from the above perspectives, particularly the perspective of obtaining effects by providing an oxide layer in the form of the composite layer of the present invention. When the composite layer is comprised of three metal oxide layers and the first and third layers are metal oxide layers with lower oxygen contents than the second layer, the thickness of both the first and third layers (one of which is a metal oxide layer with the lowest oxygen content and the other of which is a metal oxide layer with the next lowest oxygen content) are desirably 5 nm or less from the above perspectives.

The multilayer antireflective film suitably comprises a high refractive index layer and a low refractive index layer. The composite layer is suitably comprised of a metal oxide containing a metal element differing from that of the high refractive index layer and low refractive index layer.

Specifically, the multilayer antireflective film comprising a high refractive index layer and a low refractive index layer can be formed by alternately depositing oxides of differing materials. Examples of the oxide constituting the high refractive index layer are niobium oxide, tantalum oxide, and zirconium oxide. Examples of the oxide constituting the low refractive index layer are silicon dioxide and a mixed oxide of silicon and aluminum.

When the metal oxide constituting the composite layer is provided with an antireflective film comprising a composite layer, it suffices for the antireflective film to be capable of maintaining a high level of optical characteristics in a plastic lens; the metal oxide (specifically, the metal that is contained in the metal oxide) is not specifically limited. However, in the present invention, the composite layer is desirably comprised of an oxide having different electrical conductivity than the metal oxide constituting the high refractive index layer and low refractive index layer. This is because electrically conductivity cannot be achieved among the metal oxide materials that are commonly employed to prevent reflection, but they can be employed as damage-resistant films. Conversely, layers of oxides having electrical conductivity, such as indium tin oxide, afford electrical conductivity, but are not adequately resistant to damage for use throughout the high refractive index layer.

Examples of oxides that are suitable for use in the composite layer are indium tin oxide, titanium oxide, indium zinc oxide, and indium oxide. These oxides have electrical conductivity, enhance the thermal resistance of a plastic lens, and are desirable from the perspective of imparting an antistatic effect to the surface. Further, from the perspective of imparting a highly stable antistatic effect, the composite layer is desirably indium tin oxide.

When the composite layer comprises an electrically conductive oxide, the oxides in all of the layers constituting the composite layer desirably have oxygen contents that are less than the stoichiometric quantity. The electrically conductive oxide in a state of oxygen defect contains positive charge sites. When the oxygen content is less than the stoichiometric quantity, the electrical conductivity of the composite layer improves, resulting in further enhancement of the antistatic effect on the plastic lens. In that case, the oxide layer with a low oxygen content is desirably comprised of an oxide lacking oxygen within a proportion range of 0.1 to 20 molar percent relative to the stoichiometric quantity. The other layers are desirably comprised of oxides lacking oxygen in a proportion range of 1×10⁻⁵ to 10 molar percent.

In a multilayer antireflective film in which the different materials set forth above are deposited, differences in the thermal characteristics of the individual materials tend to cause fine cracks to form between layers due to thermal fatigue, resulting in internal cracking. The first object of the present invention is to solve such problems. Thus, the above-described composite layer is incorporated into the multilayer antireflective layer. When the oxygen content differs in oxides of an identical metal, the characteristics of stress-induced change vary. By having two metal oxide layers of differing oxygen content adjacent to each other, tensile stress and compressive stress caused by thermal expansion and the like can be successfully canceled out. In particular, when the oxygen in at least one layer contained in the composite layer is less than the stoichiometric quantity, some oxygen for forming bonds with the metal element will be missing in the oxide layer in this state of oxygen defect. When oxygen for forming bonds with the metal element in the layer is missing, the layer becomes soft. Due to this softness, the oxygen defect layer can suitably absorb distortion due to differences in thermal expansion rates between materials. In the present invention, internal cracking of the surface-treated layer is inhibited and the thermal resistance property of the lens is enhanced by incorporating an oxygen-defect layer into the multilayer antireflective film.

The composite layer is desirably incorporated into the above antireflective layer so that the outermost layer of the metal oxide layers constituting the composite layer is the second layer from the outside of the antireflective film. Further, the metal oxide layer with the lowest oxygen content is desirably the outermost layer of the metal oxide layers constituting the composite layer. Incorporating one oxide layer having an oxygen content of less than the stoichiometric quantity into the composite layer so that it is the second layer from the outside of the antireflective film is desirable from the perspectives of achieving good effects in the form of inhibiting internal cracking of the surface-treated layer and enhancing the thermal resistance property of the lens. The tendency of minute cracking caused by heat to occur increases toward the outer layers in an antireflective film. Forming an oxygen-defect layer immediately beneath the outermost low refractive index layer suitably inhibits minute cracking due to thermal distortion.

The plastic lens substrate is not specifically limited. Examples are methyl methacrylate homopolymer, copolymers of methyl methacrylate and one or more other monomer, diethylene glycol bisallylcarbonate homopolymer, copolymers of diethylene glycol bisallylcarbonate and one or more other monomer, sulfur-containing copolymers, halogen-containing copolymers, polycarbonate, polystyrene, polyvinyl chloride, unsaturated polyester, polyethylene terephthalate, and polyurethane. By way of example, the refractive index of the plastic lens substrate is desirably 1.5 to 1.8.

In the plastic lens of the present invention, an underlayer is desirably provided between the plastic lens substrate and the antireflective film. The underlayer is desirably a silicon dioxide layer. Further, metallic niobium can be vapor deposited prior to forming the underlayer.

A hard coating film can be present between the plastic lens substrate and the antireflective layer or underlayer in the plastic lens of the present invention. A cured composition comprised of metal oxide colloidal particles and an organic silicon compound is generally employed as the hard coating film. Examples of the metal oxide colloidal particles are: tungsten oxide (WO₃), zinc oxide (ZnO), silicon oxide (SiO₂), aluminum oxide (Al₂O₃), titanium oxide (TiO₂), zirconium oxide (ZrO₂), tin oxide (SnO₂), beryllium oxide (BeO), and antimony oxide (Sb₂O₅). They may be employed singly or in combinations of two or more.

A primer layer can be formed to enhance adhesion between the hard coating film and the plastic lens substrate. Forming a primer layer has the effect of enhancing the impact resistance of the plastic lens. A urethane-based material is an example of the material constituting the primer layer.

As needed, a water-repellent layer can be provided over the outermost layer of the antireflective film.

### The Method for Manufacturing a Plastic Lens

The method for manufacturing a plastic lens of the present invention will be described next.

The antireflective film is prepared by alternately depositing different oxide materials to form a high refractive index layer and a low refractive index layer. In this process, the oxide layer with a low oxygen content in the composite layer is formed by vapor deposition under conditions in which less reactive oxygen gas is supplied (that is, an environment with a low oxygen partial pressure) than when forming the adjacent oxide film. In addition to the oxide layer with a low oxygen content, layers constituting the composite layer and portions of the antireflective film other than the composite layer are also desirably formed by vapor deposition from the perspective of simplifying the manufacturing method.

The composite layer can be formed, for example, by forming an oxide layer under the usual reactive oxygen gas feed level conditions, and then forming over the surface thereof an adjacent film under reactive oxygen gas feed level conditions to achieve a low oxygen content and obtain a two-layer structure composite layer with overlapping oxide layers. Alternatively, an oxide layer can be formed under the usual reactive oxygen gas feed level conditions and films can be formed above and below this oxide layer under reactive oxygen gas feed level conditions that yield low oxygen contents to obtain a three-layer structure composite layer with overlapping oxide layers. As set forth above, a composite layer with at least a two-layer structure in which the upper (surface-side) layer has a lower oxygen content than the lower (substrate-side) layer is an example of an implementation mode that efficiently imparts a thermal resistance property by means of a composite layer. Since heat is applied from the upper (surface) side toward the lower (substrate) side in a plastic lens, positioning a layer with a low oxygen content as the upper layer in a composite layer effectively enhances the heat resistance property of the plastic lens.

Examples of methods of vapor deposition in the presence of reactive oxygen gas are: ion plating, plasma CVD, the ion-assisted method, and reactive sputtering. Such methods permit the adjustment of the feed level of reactive oxygen gas, thereby permitting the formation of an oxide layer of low oxygen content. In particular, use of the ion-assisted method is desirable from the perspective of obtaining a dense layer in which microscopic voids do not form in the layers.

Methods of vapor deposition in the presence of reactive oxygen gas, such as ion-assisted vapor deposition, are known. The degree of oxidation of the oxide can be controlled by the formation of vapor deposited films by conducting vapor deposition in a reactive oxygen gas atmosphere. In particular, regulation of the quantity of oxygen gas ions by ion-assisted vapor deposition permits ready adjustment of the level of oxygen defect in the layer. The level of oxygen gas ions can be regulated by suitably admixing inert gases such as argon gas to the oxygen gas.

The degree of oxidation in the layer can be specified by adjusting the level of oxygen by the oxygen-assisted method. As a result, a lens with good thermal resistance can be obtained while maintaining a high level of optical characteristics in the lens.

As set forth above, in the antireflective film of the plastic lens of the present invention, a layer containing an oxide layer with a lower oxygen content than the adjacent oxide layer is desirably contained in the composite layer, and the presence of other oxide layers in the composite layer that are identical in composition to the oxide layer with a low oxygen content except for their oxygen content is desirable. In that case, in the composite layer, both the layer of low oxygen content and the other layers that are identical in composition to it except for their oxygen content are desirably formed by ion-assisted vapor deposition. Specifically, the oxide layer of low oxygen content and the other oxide layers of identical composition except for their oxygen content are formed by ion-assisted vapor deposition using an identical vaporization source and varying the concentration of oxygen gas in multiple implementations. Since employing a single vaporization source and simply varying the concentration of oxygen gas permits the formation of oxide layers of different oxygen content, the manufacturing method is greatly simplified. Since films can be formed simply by adjusting the oxygen level during film formation, a layer with a low degree of oxidation can be readily formed.

In addition to an antireflective effect, the formation of the composite layer with an electrically conductive oxide imparts electrical conductivity. Films of electrically conductive oxides (such as InSnO, InZnO, and In₂O₃) can generally be formed while feeding reactive oxygen gas. Further, including a vapor deposition step under conditions of a low oxygen feed level lowers the surface resistivity of the antireflective film obtained. This also inhibits variation in surface resistivity between individual lenses.

The present invention yields a plastic lens having both a good thermal resistance property and a good antireflective effect with little coloration. The present invention is particularly suited to the forming of antireflective films on plastic lenses for use in eyeglasses.

### EMBODIMENTS

The present invention is described in greater detail below through embodiments.

### Embodiment 1

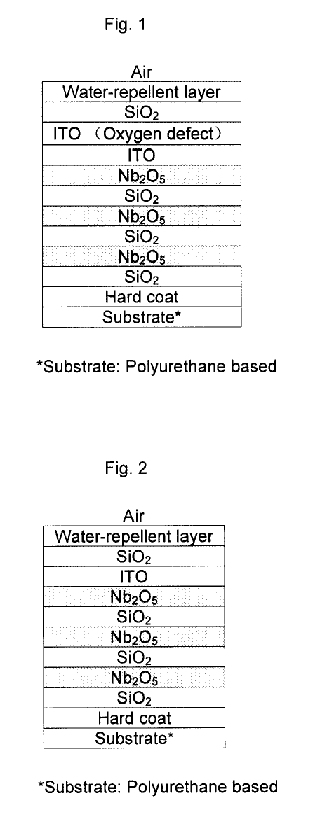

Sixteen samples of the present embodiment were prepared under the following conditions. The layer configuration is shown in FIG. 1.

A first layer serving as an underlayer (low refractive index layer) in the form of a silicon oxide layer was formed on the surface of a plastic substrate (plastic lens with a refractive index of 1.53; product name: Phoenix; made by HOYA Corporation) on which a hard coat had been applied in advance. Layers 2 through 9 were then applied thereover to form an antireflective film.

Layers 1, 3, 5, and 9 were formed by vapor depositing a low refractive index material in the form of silicon oxide by vacuum vapor deposition.

Layers 2, 4, and 6 were formed by vapor depositing a high refractive index material in the form of niobium oxide by vacuum vapor deposition.

Layers 7 and 8 were formed as ITO layers by conducting oxide layer-forming ion-assisted vapor deposition while introducing oxygen gas ions. Layer 7 was formed by introducing just oxygen gas ions. Layer 8 was formed by introducing oxygen gas ions and argon gas ions. The oxygen gas ions introduced were more numerous in layer 7 than in layer 8 so that the degree of oxidation of the ITO in layer 8 was lower. ITO layers with low degrees of oxidation generally have high light absorptivity. As the thickness of layer 8 increased, the absorptivity of the lens itself also increased. Thus, layer 8 was set to a thickness of 5 nm or lower to obtain an optical layer thickness that minimized the increase in absorptivity.

Table 1 gives the film forming conditions and configuration of the antireflective film. The thickness of the film was controlled during film formation by optical film thickness measurement. The optical film thickness in Table 1 is given for a wavelength of λ(lambda)=500 nm. The actual film thickness was calculated from the integrated value of the optical film thickness and the refractive index.

### <Vapor Deposition Structures>

TABLE 1

| | | | Optical | | | Ion gun | |
|---|---|---|---|---|---|---|---|
| | | Physical film | film | | | conditions | |
| | | thickness | thickness | Refractive | | Voltage | Current |
| Layer | Material | (nm) | (nm) | index | Ar/O₂ | (V) | (mA) |
| 1 | SiO₂ | 20-22 | 0.059-0.065 | 1.43-1.47 | — | — | — |
| 2 | Nb₂O₅ | 3-4 | 0.014-0.018 | 2.05-2.35 | — | — | — |
| 3 | SiO₂ | 195-200 | 0.574-0.588 | 1.43-1.47 | — | — | — |
| 4 | Nb₂O₅ | 24-26 | 0.109-0.118 | 2.05-2.35 | — | — | — |
| 5 | SiO₂ | 32-34 | 0.094-0.100 | 1.43-1.47 | — | — | — |
| 6 | Nb₂O₅ | 28-30 | 0.127-0.136 | 2.05-2.35 | — | — | — |
| 7 | ITO | 6-12 | 0.026-0.051 | 2.00-2.10 | 0/40 | 260 | 160 |
| 8 | ITO | <5 | <0.02 | 2.00-2.10 | 10/10 | 260 | 160 |
| 9 | SiO₂ | 94-97 | 0.277-0.285 | 1.43-1.47 | — | — | — |

* Layer one was the layer closest to the substrate, and layer 9 was the outermost layer.

### Comparative Example 1

Sixteen samples of the comparative example were prepared under the following conditions. FIG. 2 gives the film configuration.

In the present comparative example, 16 samples were prepared with antireflective films of the configuration of the antireflective film of Embodiment 1, but without forming the ITO (oxygen-defect layer) of layer 8. Table 2 gives the film forming conditions and structure of the antireflective film.

TABLE 2

| | | | | | | Ion gun | |
|---|---|---|---|---|---|---|---|
| | | Physical film | Optical film | | | conditions | |
| | | thickness | thickness | Refractive | | Voltage | Current |
| Layer | Material | (nm) | (nm) | index | Ar/O₂ | (V) | (mA) |
| 1 | SiO₂ | 20-22 | 0.059-0.065 | 1.43-1.47 | — | — | — |
| 2 | Nb₂O₅ | 3-4 | 0.014-0.018 | 2.05-2.35 | — | — | — |
| 3 | SiO₂ | 195-200 | 0.574-0.588 | 1.43-1.47 | — | — | — |
| 4 | Nb₂O₅ | 24-26 | 0.109-0.118 | 2.05-2.35 | — | — | — |
| 5 | SiO₂ | 32-34 | 0.094-0.100 | 1.43-1.47 | — | — | — |
| 6 | Nb₂O₅ | 28-30 | 0.127-0.136 | 2.05-2.35 | — | — | — |
| 7 | ITO | 6-12 | 0.026-0.051 | 2.00-2.10 | 0/40 | 260 | 160 |
| 8 | SiO₂ | 94-97 | 0.277-0.285 | 1.43-1.47 | — | — | — |

* Layer one was the layer closest to the substrate, and layer 8 was the outermost layer.

### Thermal Resistance Rest (i)

A thermal resistance test was conducted under the following conditions. The test was conducted by placing a lens having an antireflective film in an oven immediately after forming a vapor deposited film and heating the lens for one hour. The lens was then cooled for 10 minutes and checked for the presence of cracks. Heating was conducted in 5° C. increments from 50° C. to determine the temperature at which cracks appeared. This test was conducted on two of the embodiment lenses and two of the comparative example lenses. The results are given in Table 3.

TABLE 3

| | Thermal resistance temperature (° C.) |
|---|---|
| Embodiment 1 | 125 |
| Embodiment 2 | 125 |
| Comparative Example 1 | 110 |
| Comparative Example 2 | 115 |

From the above results, the lenses of Embodiments 1 and 2, which contained ITO layers with low oxygen contents, were found to have thermal resistance temperatures that were about 10° C. higher than those of Comparative Examples 1 and 2.

### Thermal Resistance Test (ii)

In the present test, edge processing was conducted and the thermal resistance test was conducted with the lenses mounted in frames. In the test, each of the samples was edge processed to the same shape and fixed in a frame of identical shape. The test method was identical to that of thermal resistance test (i) above. The present test was conducted on two embodiment lenses and two comparative example lenses. The results are given in Table 4.

TABLE 4

| | Thermal resistance temperature (° C.) |
|---|---|
| Embodiment 3 | 110 |
| Embodiment 4 | 105 |
| Comparative Example 3 | 100 |
| Comparative Example 4 | 100 |

From the above results, the lenses of Embodiments 3 and 4 were found to have better thermal resistance than Comparative Examples 3 and 4 by 5 to 10° C.

Even when the lenses were secured to frames and distortion was applied to the frames, the incorporation of ITO layers of low oxygen content was found to enhance thermal resistance.

### Measurement of Surface Resistivity

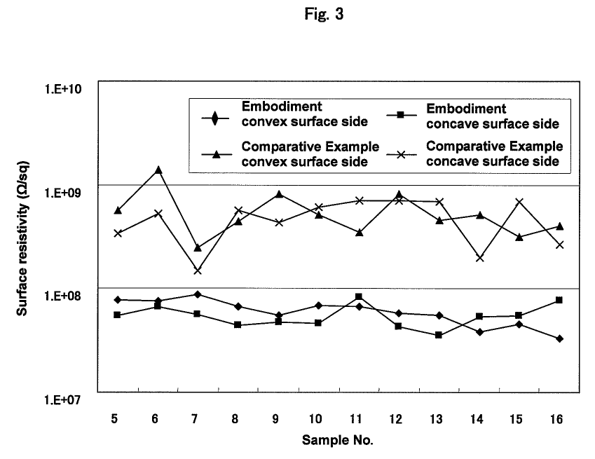

The surface resistivity of 12 samples of embodiments and 12 samples of comparative examples were measured. The results are given in Table 5 and plotted in FIG. 3.

TABLE 5

| | | | Comparative examples | |
|---|---|---|---|---|
| | Embodiments (Ω/□) | | (Ω/□) | |
| | Convex | Concave | Convex | Concave |
| Sample No. | surface side | surface side | surface side | surface side |
| 5 | 7.6E+07 | 5.5E+07 | 5.71E+08 | 3.42E+08 |
| 6 | 7.4E+07 | 6.7E+07 | 1.38E+09 | 5.22E+08 |
| 7 | 8.6E+07 | 5.6E+07 | 2.49E+08 | 1.47E+08 |
| 8 | 6.5E+07 | 4.4E+07 | 4.45E+08 | 5.62E+08 |
| 9 | 5.3E+07 | 4.8E+07 | 8.13E+08 | 4.38E+08 |
| 10 | 6.7E+07 | 4.6E+07 | 5.13E+08 | 6.13E+08 |
| 11 | 6.5E+07 | 8.3E+07 | 3.49E+08 | 7.11E+08 |
| 12 | 5.6E+07 | 4.3E+07 | 8.11E+08 | 7.02E+08 |
| 13 | 5.4E+07 | 3.5E+07 | 4.54E+08 | 6.88E+08 |
| 14 | 3.7E+07 | 5.3E+07 | 5.13E+08 | 1.99E+08 |
| 15 | 4.4E+07 | 5.5E+07 | 3.18E+08 | 6.93E+08 |
| 16 | 3.2E+07 | 7.8E+07 | 3.99E+08 | 2.66E+08 |

As is shown by Table 5 and FIG. 3, the samples of the embodiments had lower surface resistivity than the samples of the comparative examples on both convex and concave surfaces. As shown in FIG. 3, the embodiments had stable resistivity on both concave and convex surfaces and there was little variation in resistivity between samples. By contrast, the comparative examples exhibited variation in resistivity between samples, with the variation in resistivity on the convex surface being particularly pronounced.

The present invention is useful in fields relating to plastic lenses.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

What is claimed is:

1. A plastic lens having a multilayer antireflective film present on the surface of a plastic lens substrate, either directly or through another layer, wherein said multilayer antireflective film comprises a composite layer in which at least two metal oxide layers, containing an identical metal element but different quantities of oxygen, are adjacent.

2. The plastic lens according to claim 1, wherein at least one layer of said metal oxide layers constituting said composite layer has an oxygen content that is less than the stoichiometric quantity.

3. The plastic lens according to claim 1, wherein all of the metal oxide layers constituting said composite layer are comprised of oxides the oxygen contents of which are less than the stoichiometric quantity.

4. The plastic lens according to claim 1, wherein the thickness of the metal oxide layer with the lowest oxygen content constituting said composite layer is 5 nm or lower.

5. The plastic lens according to claim 1, wherein said composite layer is comprised of two metal oxide layers.

6. The plastic lens according to claim 1, wherein said multilayer antiresistive film comprises a high refractive index layer and a low refractive index layer, and said composite layer is comprised of metal oxides containing metal elements differing from those of said high refractive index layer and said low refractive index layer.

7. The plastic lens according to claim 1, wherein said composite layer is contained within said antireflective film so that the outermost layer of the metal oxide layers constituting said composite layer is the second layer from the outside of said antireflective film.

8. The plastic lens according to claim 7, wherein said outermost layer of the metal oxide layers constituting said composite layer is the metal oxide layer of the lowest oxygen content.

9. The plastic lens according to claim 1, wherein said metal oxide layers constituting said composite layer are comprised of an electrically conductive oxide.

10. The plastic lens according to claim 1, wherein said metal oxide layers constituting said composite layer are comprised of indium tin oxide, titanium oxide, indium zinc oxide, or indium oxide.

11. A method for manufacturing the plastic lens having a multilayer antireflective film present on the surface of a plastic lens substrate, either directly or through another layer, wherein said multilayer antireflective film comprises a composite layer in which at least two metal oxide layers, containing an identical metal element but different quantities of oxygen, are adjacent;
wherein each of the metal oxide layers constituting said composite layer is formed by employing a single vaporization source and by vapor depositing adjacent layers under differing conditions of partial pressure of reactive oxygen gas.

12. The manufacturing method of claim 11, wherein said vapor deposition is conducted by a method selected from the group consisting of ion plating, plasma CVD, the ion-assisted method, and reactive sputtering.

13. The manufacturing method according to claim 11, wherein said vapor deposition is conducted by the ion-assisted method.

14. The manufacturing method according to claim 11, wherein said multilayer antiresistive film comprises a high refractive index layer and a low refractive index layer, and said composite layer is comprised of metal oxides containing metal elements differing from those of said high refractive index layer and said low refractive index layer.

15. The manufacturing method according to claim 14, wherein a high refractive index layer and a low refractive index layer are repeatedly deposited any number of times and in any order, either directly or through another layer, on the surface of a plastic lens substrate, and said composite layer is formed on the high refractive index layers and low refractive index layers that have been thus deposited.
